(19) United States
(12) Patent Application Publication
(10) Pub. No.: US 2014/0199854 A1
(43) Pub. Date: Jul. 17, 2014

(54) METHOD OF FORMING FILM ON DIFFERENT SURFACES

(71) Applicant: UNITED MICROELECTRONICS CORP., Hsinchu (TW)

(72) Inventors: Chih-Chung Chen, Tainan City (TW); Tsuo-Wen Lu, Kaohsiung City (TW); Yu-Ren Wang, Tainan City (TW)

(73) Assignee: UNITED MICROELECTRONICS CORP., HSINCHU (TW)

(21) Appl. No.: 13/742,467

(22) Filed: Jan. 16, 2013

(51) Int. Cl. H01L 21/02

(52) U.S. Cl. CPC H01L 21/02312
USPC 438/775

(57) ABSTRACT

A method of forming a film is provided. The method includes at least the following steps. A first substrate and a second substrate are provided in a batch processing system, wherein a first surface of the first substrate is adjacent to a second surface of the second substrate, the first surface of the first substrate has a first surface condition, the second surface of the second substrate has a second surface condition, and the first surface condition is different from the second surface condition. A pretreatment gas is provided to the surfaces of the substrates for transforming the first surface condition and the second surface condition to a third surface condition. A reaction gas is provided to form the film on the surfaces, having the third surface condition, of the substrates.

### BACKGROUND OF THE INVENTION

1. Field of the Invention

The disclosure relates in general to a method of forming a film, and more particularly to a method of forming a film on different surfaces.

2. Description of the Related Art

In semiconductor structures, silicon nitride films are usually applied as etching stop layers or hard masks. Silicon nitride films formed by an atomic layer deposition (ALD) have superior etching resistance and great within wafer uniformity. Besides, an ultra-thin film thickness of silicon nitride films can be manufactured by the atomic layer deposition process. Therefore, such films are extensively applied in semiconductor structures.

However, when silicon nitride films are formed on wafers by the atomic layer deposition process in a batch process, there is a large variation between the thicknesses of the silicon nitride films formed on different wafers.

That is to say, the wafer to wafer uniformity of the silicon nitride films is poor. As such, researchers are working on studying and solving such problems.

### SUMMARY OF THE INVENTION

The disclosure is directed to a method of forming a film on different surfaces. Before the film is formed, a pretreatment gas is provided to the surfaces of the substrates, such that the surfaces of the substrates can have the same surface condition, and accordingly, the growth rates of the film on different surfaces of the various substrates can be very close or substantially the same. As such, the uniformity of the thicknesses of the film on various substrates can be increased.

According to an aspect of the present disclosure, a method of forming a film with a batch process is disclosed. The method includes at least the following steps. A first substrate and a second substrate are provided in a batch processing system, wherein a first surface of the first substrate is adjacent to a second surface of the second substrate, the first surface of the first substrate has a first surface condition, the second surface of the second substrate has a second surface condition, and the first surface condition is different from the second surface condition. A pretreatment gas is provided to the surfaces of the substrates for transforming the first surface condition and the second surface condition to a third surface condition. A reaction gas is provided to form the film on the surfaces, having the third surface condition, of the substrates.

According to another aspect of the present disclosure, a method of forming a nitride film is disclosed. The method includes at least the following steps. A first substrate and a second substrate are provided, a first surface of the first substrate is adjacent to a second surface of the second substrate, the first surface of the first substrate has a first surface condition, the second surface of the second substrate has a second surface condition, and the first surface condition is different from the second surface condition. The first surface of the first substrate and the second surface of the second substrate are exposed to a nitrogen-containing pretreatment gas under a first operating pressure. The nitride film is formed on the first surface of the first substrate and the second surface of the second substrate under a second operating pressure by an atomic layer deposition process, wherein the second operating pressure is smaller than the first operating pressure.

The disclosure will become apparent from the following detailed description of the preferred but non-limiting embodiments. The following description is made with reference to the accompanying drawings.

### BRIEF DESCRIPTION OF THE DRAWINGS

FIGS. 1A-1B illustrate a method of forming a film according to an embodiment of the disclosure.

FIG. 2 shows a batch processing system according to the embodiment of the disclosure.

FIGS. 3A-3B illustrate manufacturing methods of forming a film on different surfaces by the atomic layer deposition process.

FIG. 4 shows a semiconductor structure with the film formed by a method according to the embodiment of the disclosure.

FIG. 5 shows a sidewall width (film thickness) distribution according to a comparative embodiment of the disclosure.

FIG. 6 shows a sidewall width (film thickness) distribution according to an embodiment of the disclosure.

### DETAILED DESCRIPTION OF THE INVENTION

In the embodiments of the disclosure, before the film is formed on different surfaces of various substrates, a pretreatment gas is provided to the surfaces of the substrates, such that the surfaces of the substrates can have the same surface condition, and accordingly, the growth rates of the film on different surfaces of the various substrates can be very close or substantially the same. As such, the uniformity of the thicknesses of the film on various substrates can be increased. The embodiments are described in details with reference to the accompanying drawings. The procedures and details of the formation method and the structure of the embodiment are for exemplification only, not for limiting the scope of protection of the disclosure. Moreover, secondary elements are omitted in the disclosure of the embodiments for highlighting the technical features of the disclosure. The identical elements of the embodiments are designated with the same reference numerals. Also, it is also important to point out that the illustrations may not be necessarily be drawn to scale, and that there may be other embodiments of the present disclosure which are not specifically illustrated. Thus, the specification and the drawings are to be regard as an illustrative sense rather than a restrictive sense.

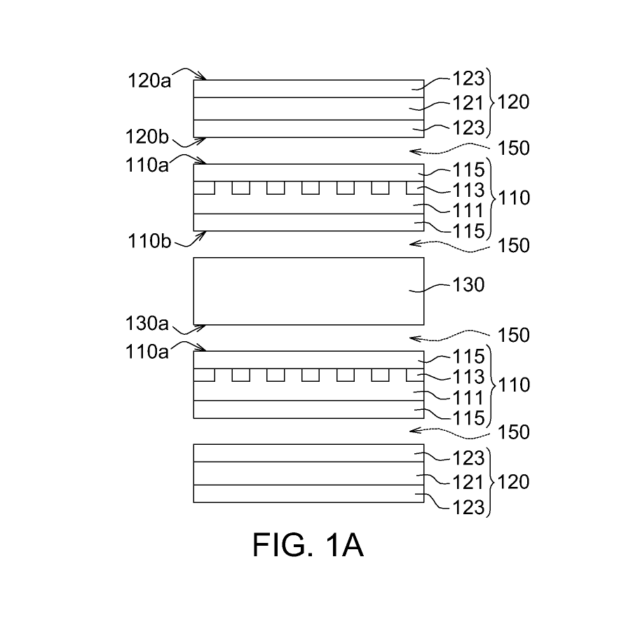

FIGS. 1A-1B illustrate a method of forming a film according to an embodiment of the disclosure. Referring to FIG. 1A, a first substrate 110 and a second substrate 120 are provided. A first surface 110a of the first substrate 110 is adjacent to a second surface 120b of the second substrate 120. The first surface 110a of the first substrate 110 has a first surface condition, and the second surface 120b of the second substrate 120 has a second surface condition which is different from the first surface condition.

In an embodiment, as shown in FIG. 1A, a second surface 110b of the first substrate 110 opposite to the first surface 110a may also have the first surface condition, and a first surface 120a of the second substrate 120 opposite to the second surface 120b may also have the second surface condition.

Next, as shown in FIG. 1 A, a pretreatment gas 150 is provided to the surfaces 110a and 120b of the substrates 110 and 120 for transforming the first surface condition and the second surface condition to a third surface condition.

In the embodiment, the first surface condition, the second surface condition, and the third surface condition can be any one of the following conditions, independently: an oxygen rich condition, a nitrogen rich condition, a carbon rich condition, and a silicon rich condition. In an embodiment, the first surface condition, the second surface condition, and the third surface condition can be different from one another. In another embodiment, the third surface condition can be the same with the first surface condition or the second surface condition.

In the embodiment, the oxygen rich condition refers to that, for example, the material of the surface of the substrate comprises an oxygen-containing material, such as metal oxide. The nitrogen rich condition refers to that, for example, the material of the surface of the substrate comprises a nitrogen-containing material, such as metal nitride. The carbon rich condition refers to that, for example, the material of the surface of the substrate comprises a carbon-containing material, such as metal carbide. The silicon rich condition refers to that, for example, the material of the surface of the substrate comprises a silicon-containing material, such as silicide.

In an embodiment, as shown in FIG. 1A, the first substrate 110 includes, for example, a silicon layer 111, a pattern layer 113, and an oxide layer 115. The pattern layer 113 is formed on the silicon layer 111, and the oxide layer 115 covers the silicon layer 111 and the pattern layer 113. The pattern layer 113 is such as a circuit pattern, and the oxide layer 115 is such as silicon oxide. The second substrate 120 includes, for example, a silicon layer 121 and a nitride layer 123. The nitride layer 123 is formed on and covers the silicon layer 121. The nitride layer 123 is such as silicon nitride. In the embodiment, the oxide layer 115 of the first substrate 110 has the first surface condition, and the nitride layer 123 of the second substrate 120 has the second surface condition. That is to say, in the embodiment, the first surface condition is the oxygen rich condition, and the second surface condition is the nitrogen rich condition.

In an embodiment, the pretreatment gas 150 is nitrogen-containing pretreatment gas, such as ammonia (NH₃). As such, in the embodiment, the third surface condition formed from the pretreatment by ammonia is the nitrogen rich condition, and a nitride film is formed on the pretreated surfaces of the substrates. In the embodiment, the surfaces of the substrates are exposed to the nitrogen-containing pretreatment gas for about 10 minutes.

In the embodiment, as shown in FIG. 1A, a third substrate 130 is further provided. For example, a first surface 130a of the third substrate 130 is adjacent to the first surface 110a of the first substrate 110. In another embodiment, the first surface 130a of the third substrate 130 can also be adjacent to the second substrate 120b of the second substrate 120 (not shown in figures). The first surface 130a of the third substrate 130 has a fourth surface condition, which is different from at least one of the first surface condition and the second surface condition.

In the embodiment, the fourth surface condition is the oxygen rich condition, the nitrogen rich condition, the carbon rich condition, or the silicon rich condition. In an embodiment, as shown in FIG. 1A, the third substrate 130 is such as a silicon layer. In the embodiment, the silicon layer of the third substrate 130 has the fourth surface condition. That is to say, in the embodiment, the fourth surface condition is the silicon rich condition.

In an embodiment, the first surface 110a of the first substrate 110 and the second surface 120b of the second substrate 120 are exposed to the pretreatment gas 150 (e.g. a nitrogen-containing pretreatment gas) under a first operating pressure for transforming the first surface condition and the second surface condition to the third surface condition. In the embodiment, the first operating pressure is, for example, larger than 0.2 torr. In an embodiment, the first surface 130a of the third substrate 130 can also be exposed to the pretreatment gas 150 (e.g. a nitrogen-containing pretreatment gas) under the first operating pressure for transforming the fourth surface condition to the third surface condition. In the embodiment, the surfaces of the first substrate 110, the second substrate 120, and the third substrate 130 can be exposed to the pretreatment gas 150 simultaneously.

Next, as shown in FIG. 1B, a reaction gas 160 is provided to form a film 180 on the surfaces having the third surface condition of the substrates 110 and 120, and the surfaces are such as the pretreated first surface 110a of the first substrate 110 and the second surface 120b of the second substrate 120. In the embodiment, the reaction gas 160 is also provided to form the film 180 on the surface having the third surface condition of the third substrate 130, and the surface is such as the pretreated first surface 130a of the third substrate 130. In the embodiment, the reaction gas 160 can be provided to the surfaces having the third surface condition of the first substrate 110, the second substrate 120, and the third substrate 130, simultaneously.

In the embodiment, the film 180 is formed on the surfaces of the substrates 110, 120, and/or 130 by, for example, a chemical vapor deposition (CVD) process or an atomic layer deposition (ALD) process.

In an embodiment, the reaction gas 160 is provided under a second operating pressure, and the second operating pressure is, for example, smaller than the first operating pressure. In the embodiment, the first operating pressure is such as larger than 0.2 torr, and the second operating pressure is such as about 0.2 torr. In other words, the pretreatment of the surfaces of the substrates is performed under a relatively high pressure.

In an embodiment, the nitride film 180 is formed on the surfaces having the third surface condition of the substrates 110, 120, and/or 130 under the second operating pressure by the atomic layer deposition process.

In an embodiment, the reaction gas includes, for example, a first reaction gas and a second reaction gas. The first reaction gas and the second reaction gas are different from each other. In an embodiment, the first reaction gas and the second reaction gas can be provided to the substrates simultaneously. In another embodiment, the first reaction gas and the second reaction gas can be provided to the substrates at different times.

In an embodiment, the operating temperature of the formation of the film 180 by the atomic layer deposition is about 630° C. The manufacturing method of the film 180 by the atomic layer deposition process includes such as the following steps.

First, the pretreated surfaces of the substrates 110 and 120 are exposed to the firs reaction gas, and the exposed surfaces are such as the first surface 110a of the first substrate 110 and the second surface 120b of the second substrate 120. In the embodiment, the first reaction gas comprises such as a nitrogen source precursor, for example, ammonia (NH₃). In the embodiment, the pretreated surface of the third substrate 130 is also exposed to the first reaction gas, and the exposed surface is such as the first surface 130a of the third substrate 130. In the embodiment, the pretreated surfaces of the substrates 110, 120, and/or 130 are exposed to the first reaction gas simultaneously.

Next, the first reaction gas is purged from the surfaces of the substrates 110, 120, and/or 130, and the purged surfaces are such as the first surface 110a of the first substrate 110, the second surface 120b of the second substrate 120, and the first surface 130a of the third substrate 130. In the embodiment, the substrates are purged with an inner gas, such as nitrogen gas.

Next, the surfaces of the substrates 110, 120, and/or 130 are exposed to the second reaction gas, and the exposed surfaces are such as the above-mentioned first surface 110a of the first substrate 110, the second surface 120b of the second substrate 120, and the first surface 130a of the third substrate 130, which have been exposed to the first reaction gas. The second reaction gas is different from the first reaction gas. The second reaction gas comprises such as a silicon source precursor, for example, dichlorosilane (DCS).

Next, the second reaction gas is purged from the surfaces of the substrates 110, 120, and/or 130. In the embodiment, the substrates are purged with an inner gas, such as nitrogen gas.

Next, the above-mentioned exposing and purging steps are repeated until the film 180 is formed. In the embodiment, the film 180 is a nitride film, such as silicon nitride (SiN).

In another embodiment, the manufacturing method of film 180 by the atomic layer deposition comprises such as the following steps.

First, as described in the above embodiments, the surfaces of the substrates 110, 120, and/or 130 are exposed to the first reaction gas, the first reaction gas is purged from the surfaces of the substrates 110, 120, and/or 130, the surfaces of the substrates 110, 120, and/or 130 are exposed to the second reaction gas, and the second reaction gas is purged from the surfaces of the substrates 110, 120, and/or 130.

Next, the pretreated surfaces of the substrates 110 and 120 are exposed to a third reaction gas, and the third reaction gas is different from the first reaction gas and the second reaction gas. The third reaction gas comprises, for example, a carbon source precursor, such as ethylene (C₂H₄). In the embodiment, the pretreated surface of the third substrate 130 is also exposed to the third reaction gas, and the exposed surface is such as the first surface 130a of the third substrate 130.

Next, the third reaction gas is purged from the surfaces of the substrates 110, 120, and/or 130, and the purged surfaces are such as the first surface 110a of the first substrate 110, the second surface 120b of the second substrate 120, and the first surface 130a of the third substrate 130. In the embodiment, the substrates are purged with an inner gas, such as nitrogen gas.

Next, the above-mentioned exposing and purging steps are repeated until the film 180 is formed. In the embodiment, the film 180 is a carbon nitride film, such as silicon carbon nitride (SiCN).

In an embodiment, the pretreated surfaces of the substrates 110, 120, and 130 can also be exposed to the second reaction gas and the third reaction gas simultaneously, and the third reaction gas is different from the first reaction gas and the second reaction gas.

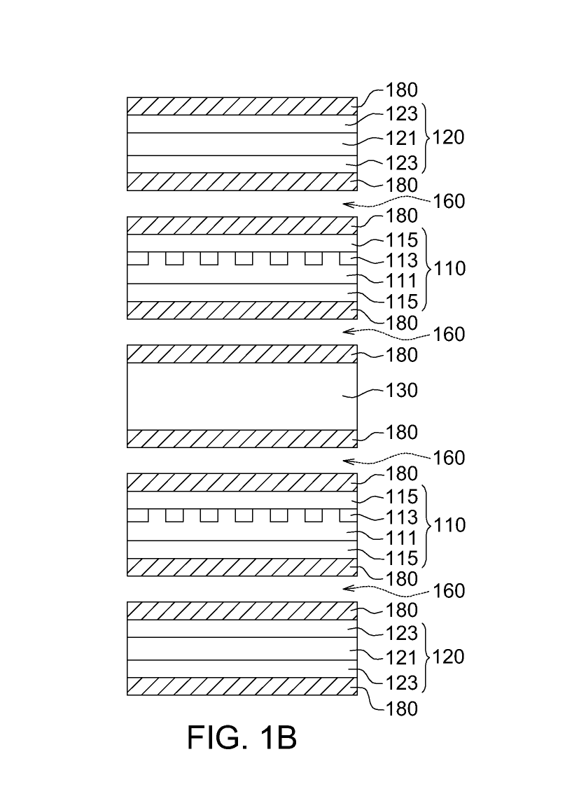

FIG. 2 shows a batch processing system according to the embodiment of the disclosure. Referring to FIG. 2, the manufacturing method of a film according to the embodiment of the disclosure can be applied to a batch process. As shown in FIG. 2, the batch processing system 100 can be disposed with a plurality of substrates of different types. The different substrates are disposed in different regions of the batch processing system 100, such as in region P, region M, or region D. In the embodiment, as shown in FIG. 2, the first substrate 110, the second substrate 120, and the third substrate 130 can provided in the batch processing system 100. For example, the first substrate 110 is disposed in region P, the second substrate 120 is disposed in region D, and the third substrate 130 is disposed in region M. In an embodiment, the batch processing system 100 is disposed with a plurality of the first substrates 110, a plurality of the second substrates 120, and a plurality of the third substrates 130. The first substrates 110 are such as production wafers with circuit patterns, the second substrates 120 are such as dummy wafers, and the third substrates 130 are such as monitor wafers.

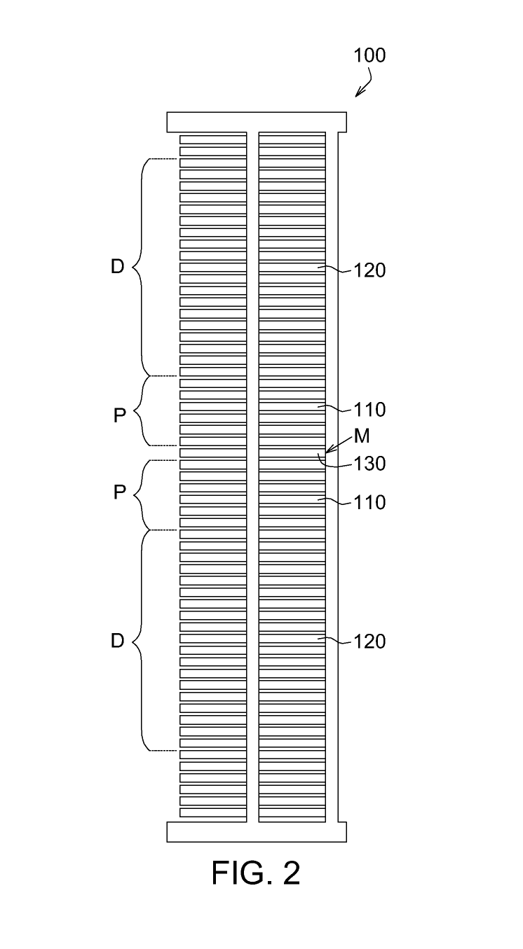

FIGS. 3A-3B illustrate manufacturing methods of forming a film on different surfaces by the atomic layer deposition process. As shown in FIG. 3A, the surfaces of the first substrate 110 and the second substrate 120 are not pretreated and have different surface conditions. In the embodiment, the oxide layer 115 on the surface of the first substrate 110 is silicon dioxide, the nitride layer 123 on the surface of the second substrate 120 is silicon nitride, and the first reaction gas 160a is ammonia. The first reaction gas 160a is introduced and flows to the gaps G1 and G2 between the first substrates 110 and the second substrates 120. When ammonia (the first reaction gas 160a) flows into the gap G1, of which the two sides are provided with silicon nitride and silicon dioxide, ammonia prefers to form a nitride monolayer on the surface of silicon dioxide (surface of the oxide layer 115). When ammonia flows into the gap G2, of which both sides are provided with silicon dioxide, ammonia substantially distributes evenly on silicon dioxide on both sides (surfaces of the oxide layers 115) to form nitride monolayers on both sides. As such, the amount of ammonia introduced to each of the two sides of the gap G2 is substantially less than the amount of ammonia introduced to the silicon dioxide side of the gap G1, such that the silicon nitride film formed on the silicon dioxide side of the gap G1 is relatively thicker, and the silicon nitride film formed on both silicon dioxide sides of the gap G2 is relatively thinner. Accordingly, the thicknesses of the film formed on different substrates are different, and substrate to substrate uniformity of the film thickness formed thereon is poor.

Besides, when silicon nitride film is to be formed on different surfaces, the adsorption rate of silicon nitride to the precursor of silicon nitride film is higher than that of silicon to the precursor of silicon nitride film, and the adsorption rate of silicon to the precursor of silicon nitride film is higher than that of silicon dioxide to the precursor of silicon nitride film. As shown in FIG. 3B, the surfaces of the first substrate 110 and the second substrate 120 are not pretreated and have different surface conditions. In the embodiment, the nitride layer 123 on the surface of the second substrate 120 is silicon nitride, the surface of the third substrate is silicon, the first reaction gas 160a is ammonia, and the second reaction gas 160b is dichlorosilane. Therefore, ammonia (the first reaction gas 160a) and dichlorosilane (the second reaction gas 160b) flowing into the gap G3 prefer to flow to the surface of silicon, such that the silicon nitride film the silicon nitride film formed on the surface 130a of the third substrate 130 is relatively thicker. Accordingly, the thicknesses of the film formed on different substrates are different, and substrate to substrate uniformity of the film thickness formed thereon is poor.

In contrast, in the embodiments of the disclosure, the pretreatment gas 150 is provided to the surfaces of the substrates before the film 180 is formed, such that the pretreated surface of the substrates can have substantially the same surface conditions. And hence, the adsorption rates of different surfaces of the various substrates can be very close or substantially the same, and accordingly, the growth rates of the film on different surfaces of the various substrates can be very close or substantially the same. As such, the uniformity of the thicknesses of the film on various substrates can be increased.

The embodiment is described in details as follows. The procedures and details of the formation method of the embodiment are for exemplification only, not for limiting the scope of protection of the disclosure.

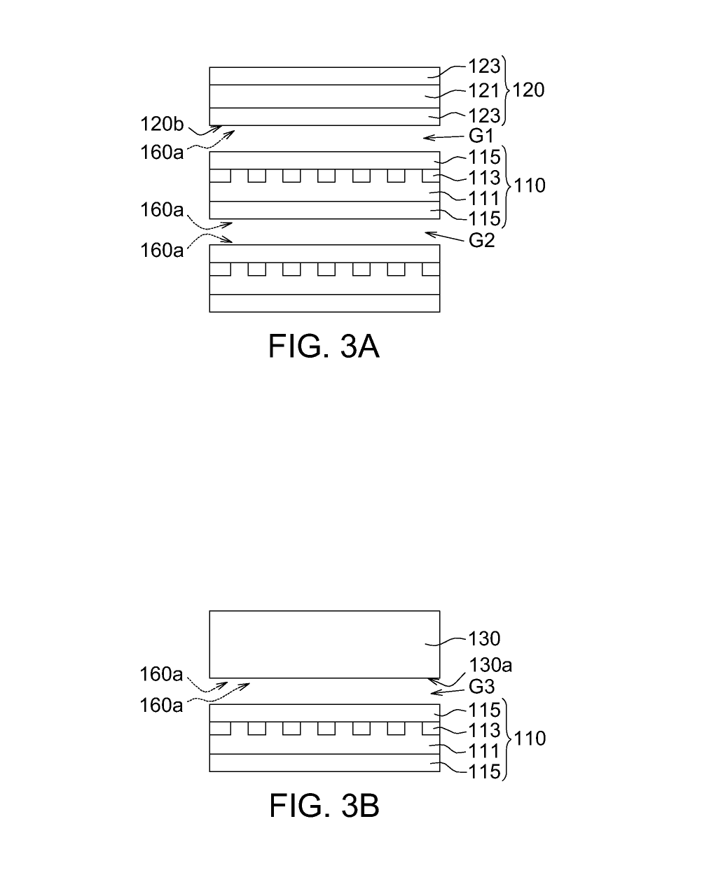

FIG. 4 shows a semiconductor structure with the film formed by a method according to the embodiment of the disclosure. As shown in FIG. 4, the semiconductor structure 400 includes a gate structure 410 and an offset spacer 420, wherein the offset spacer 420 (film 180) is formed on the sidewalls of the gate structure 410 by a method of forming the film 180 according to the embodiment of the disclosure.

The manufacturing method of forming the semiconductor structure 400 including the offset spacer 420 (film 180) comprises such as the following steps. The gate structure 410 is formed, the implant areas of the semiconductor structure 400 are annealed to be activated, a film 180 is formed on the gate structure 410 by a manufacturing method according to the embodiment of the disclosure, and the film 180 is etched to form the offset spacer 420 as shown in FIG. 4.

The manufacturing method of the film 180 according to the embodiments of the disclosure is not limited to the formation of the offset spacer 420 as shown in FIG. 4. The method of forming the film 180 according to the embodiments of the disclosure can also be applied on forming hard masks.

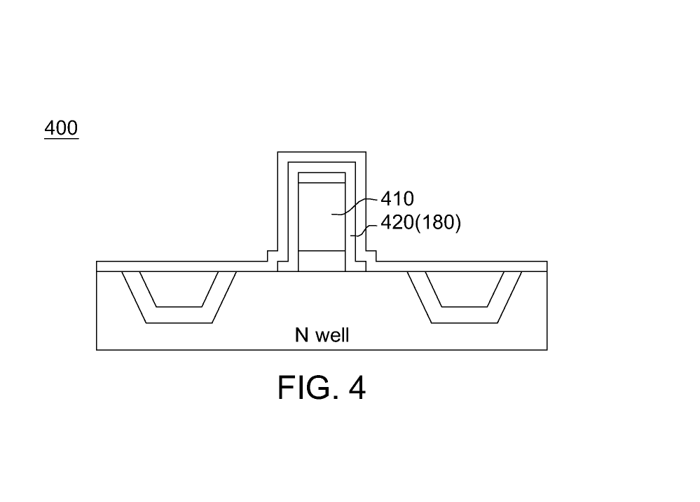

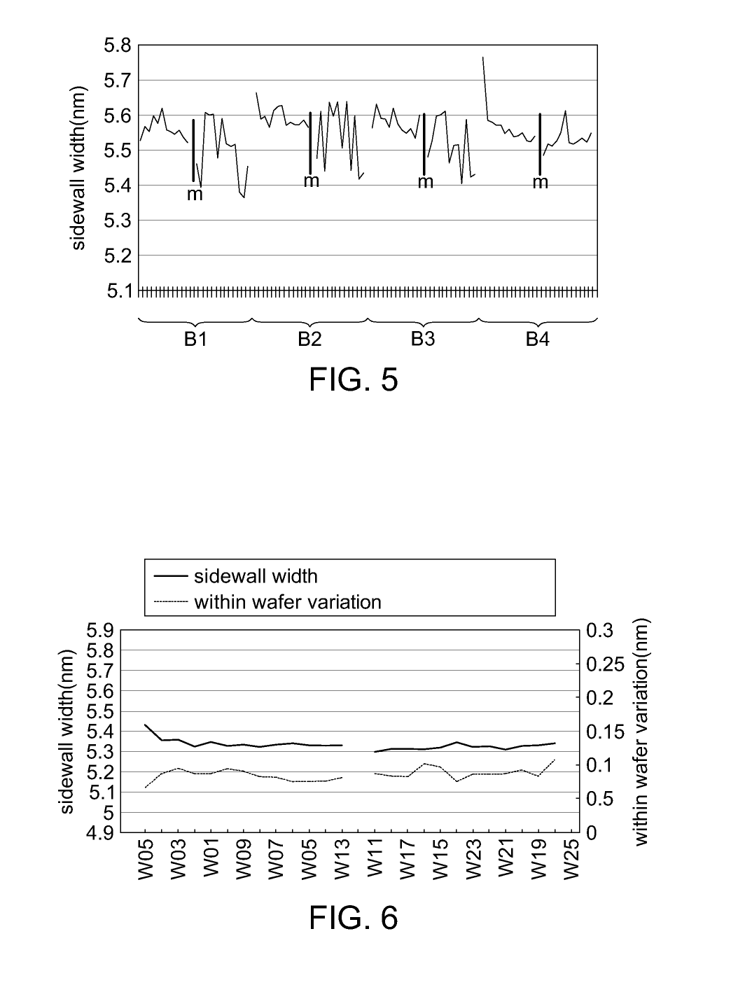

FIG. 5 shows a sidewall width (film thickness) distribution according to a comparative embodiment of the disclosure. FIG. 6 shows a sidewall width (film thickness) distribution according to an embodiment of the disclosure. In both embodiments, the first substrates 110, the second substrates 120, and the third substrates 130 are disposed in a batch processing system, as shown in FIG. 2, and the first substrates 110, the second substrates 120, and the third substrates 130 are such as production wafers, dummy wafers, and monitor wafers. Films 180 are formed on the surfaces of substrates (wafers) by the atomic layer deposition process. And then, the films 180 are etched to form the offset spacers as shown in FIG. 4, followed by the measurement of the sidewall widths of the offset spacers. In both embodiments, the oxide layer 115 on the surface of the first substrate 110 is silicon dioxide, the nitride layer 123 on the surface of the second substrate 120 is silicon nitride, the surface of the third substrate 130 is silicon, the first reaction gas 160a is ammonia, the second reaction gas 160b is dicholorosilane, and the film 180 is silicon nitride. The difference between the comparative embodiment and the embodiment is that, the substrates (wafers) in the embodiment are pretreated with ammonia (pretreatment gas 150) under a pressure of larger than 0.2 torr before forming silicon nitride under a pressure of about 0.2 torr by the atomic layer deposition process, and the substrates (wafers) in the comparative embodiment are not pretreated.

In both embodiments, the sidewall widths are measured as follows.

Twenty-one positions of the offset spacer 420 (film 180) on a single substrate (wafer) are chosen, and the sidewall widths (thicknesses) of the twenty-one positions are measured to obtain twenty-one measured values. An average sidewall width is obtained by averaging the twenty-one measured values. Besides, among the twenty-one measured values, the difference between the maximum value and the minimum value defines the within wafer variation of the offset spacer 420 (film 180).

As shown in FIG. 5, four batches B1-B4 of sidewall widths are shown. Each batch includes twenty-five wafers, the wafer m indicates the monitor wafer (third substrate 130), and the other wafers are the first substrates 110 and the second substrates 120. As shown in FIG. 5, in the comparative embodiment, in the four batches B1-B4, the sidewall width distribution of the offset spacers manufactured by a batch process is in the range of 5.37-5.67 nm, wherein the maximum difference is about 0.30 nm. In contrast, as shown in FIG. 6, in the embodiment, wafers W01-W25 represent the twenty-five wafers provided in a batch, and the sidewall width distribution of the offset spacers 420 (film 180) formed on the wafers W01-W25 by a batch process is in the range of 5.299-5.429 nm, wherein the maximum difference is about 0.13 nm. Accordingly, in the embodiment, after the wafers with different surface conditions are pretreated, the variation between the sidewall widths of the offset spacers formed on different wafers is reduced. In other words, according to the manufacturing method of the embodiment of the disclosure, the wafer to wafer uniformity of the thickness of the film 180 is largely improved.

In addition, as shown in FIG. 6, in the embodiment, the within wafer sidewall width variations of the offset spacers 420 (films 180) formed on wafers W01-W25 are all lower than 0.102. In other words, according to the manufacturing method of the embodiment of the disclosure, the uniformity of the thickness of the film 180 formed on single wafer is improved as well.

The table below shows the statistic sigma values and statistic values of within wafer uniformity (%) of the sidewall widths (film thicknesses) of the offset spacers 420 (films 180). The statistic value of within wafer uniformity (%) is calculated as follows: (sigma value/average sidewall width)*100%. That is to say, the smaller the value of within wafer uniformity (%) is, the smaller the within wafer sidewall width variation is, and the higher the within wafer uniformity of the offset spacer (film) is. Besides, in the table, the values in group A are calculated from the original measured values of sidewall widths (each wafer has twenty-one measured values) from the twenty-five wafers, and the values in group B are calculated from the average sidewall widths from the twenty-five wafers.

| | | Comparative | |
|---|---|---|---|
| | | Embodiment | Embodiment |
| | | (one batch) | (one batch) |
| Group A | Sigma | 0.05 nm | 0.03 nm |
| | Within wafer uniformity (%) | 0.95% | 0.63% |
| Group B | Sigma | 0.05 nm | 0.024 nm |
| | Within wafer uniformity (%) | 0.86% | 0.46% |

As shown in the above table, the sigma value is decreased from 0.05 nm provided by the comparative embodiment to 0.024-0.03 nm provided by the embodiment. The sigma value is decreased by about 0.02-0.026 nm, which represents an improvement of the wafer to wafer uniformity of the sidewall width (film thickness) of the offset spacer (film). Furthermore, the within wafer uniformity percentage is decreased from 0.95-0.86% to 0.63-0.46%. The sidewall width variation within single wafer is reduced, which represents a great improvement of the within wafer uniformity of the sidewall width.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of forming a film with a batch process, comprising:
providing a first substrate and a second substrate in the batch processing system, wherein a first surface of the first substrate is adjacent to a second surface of the second substrate, the first surface of the first substrate has a first surface condition, the second surface of the second substrate has a second surface condition, and the first surface condition is different from the second surface condition;
providing a pretreatment gas to the surfaces of the substrates for transforming the first surface condition and the second surface condition to a third surface condition; and
providing a reaction gas to form the film on the surfaces, having the third surface condition, of the substrates.

2. The method of forming the film according to claim 1, wherein the first surface condition, the second surface condition, and the third surface condition are one of an oxygen rich condition, a nitrogen rich condition, a carbon rich condition, and a silicon rich condition, respectively.

3. The method of forming the film according to claim 1, wherein the third surface condition is the same with the first surface condition or the second surface condition.

4. The method of forming the film according to claim 1, wherein the pretreatment gas is provided under a first operating pressure, the reaction gas is provided under a second operating pressure, and the second operating pressure is smaller than the first operating pressure.

5. The method of forming the film according to claim 4, wherein the first operating pressure is larger than 0.2 torr.

6. The method of forming the film according to claim 1, wherein the pretreatment gas is ammonia (NH₃).

7. The method of forming the film according to claim 1, wherein the film is formed on the surfaces of the substrates by a chemical vapor deposition (CVD) process or an atomic layer deposition (ALD) process.

8. The method of forming the film according to claim 7, wherein the reaction gas comprises a first reaction gas and a second reaction gas, and the step of forming the film by the atomic layer deposition process comprises:
exposing the first surface of the first substrate and the second surface of the second substrate to the first reaction gas, wherein the first reaction gas comprises a nitrogen source precursor;
purging the first reaction gas from the first surface of the first substrate and the second surface of the second substrate;
exposing the first surface of the first substrate and the second surface of the second substrate to the second reaction gas, wherein the second reaction gas is different from the first reaction gas;
purging the second reaction gas from the first surface of the first substrate and the second surface of the second substrate; and
repeating the exposing and purging steps until the film is formed, wherein the film is a nitride film.

9. The method of forming the film according to claim 1, further comprising:
providing a third substrate in the batch processing system, wherein a first surface of the third substrate is adjacent to the first surface of the first substrate or the second surface of the second substrate, the first surface of the third substrate has a fourth surface condition different from at least one of the first surface condition and the second surface condition;
providing the pretreatment gas to the first surface of the third substrate for transforming the fourth surface condition to the third surface condition; and
providing the reaction gas to form the film on the first surface, having the third surface condition, of the third substrate.

10. The method of forming the film according to claim 9, wherein the fourth surface condition is one of an oxygen rich condition, a nitrogen rich condition, a carbon rich condition, and a silicon rich condition.

11. A method of forming a nitride film, comprising:
providing a first substrate and a second substrate, wherein a first surface of the first substrate is adjacent to a second surface of the second substrate, the first surface of the first substrate has a first surface condition, the second surface of the second substrate has a second surface condition, and the first surface condition is different from the second surface condition;
exposing the first surface of the first substrate and the second surface of the second substrate to a nitrogen-containing pretreatment gas under a first operating pressure; and
forming the nitride film on the first surface of the first substrate and the second surface of the second substrate under a second operating pressure by an atomic layer deposition process, wherein the second operating pressure is smaller than the first operating pressure.

12. The method of forming the nitride film according to claim 11, wherein the first operating pressure is larger than 0.2 torr.

13. The method of forming the nitride film according to claim 11, wherein the second operating pressure is about 0.2 torr.

14. The method of forming the nitride film according to claim 11, wherein the nitrogen-containing pretreatment gas is ammonia.

15. The method of forming the nitride film according to claim 11, wherein the first surface of the first substrate and the second surface of the second substrate are exposed to the nitrogen-containing pretreatment gas for about 10 minutes.

16. The method of forming the nitride film according to claim 11, wherein the step of forming the nitride film by the atomic layer deposition process comprises:
exposing the first surface of the first substrate and the second surface of the second substrate to a first reaction gas, wherein the first reaction gas comprises a nitrogen source precursor;
purging the first reaction gas from the first surface of the first substrate and the second surface of the second substrate;
exposing the first surface of the first substrate and the second surface of the second substrate to a second reaction gas, wherein the second reaction gas is different from the first reaction gas;
purging the second reaction gas from the first surface of the first substrate and the second surface of the second substrate; and
repeating the exposing and purging steps until the nitride film is formed.

17. The method of forming the nitride film according to claim 16, wherein the second reaction gas comprises a silicon source precursor.

18. The method of forming the nitride film according to claim 16, wherein the step of forming the nitride film by the atomic layer deposition process further comprises:
exposing the first surface of the first substrate and the second surface of the second substrate to a third reaction gas, wherein the third reaction gas is different from the first reaction gas and the second reaction gas; and
purging the third reaction gas from the first surface of the first substrate and the second surface of the second substrate.

19. The method of forming the nitride film according to claim 18, wherein the third reaction gas comprises a carbon source precursor.

20. The method of forming the nitride film according to claim 11, further comprising:
providing a third substrate, wherein a first surface of the third substrate is adjacent to the first surface of the first substrate or the second surface of the second substrate, the first surface of the third substrate has a fourth surface condition different from at least one of the first surface condition and the second surface condition;
exposing the first surface of the third substrate to the nitrogen-containing pretreatment gas under the first operating pressure; and
forming the nitride film on the first surface of the third substrate under the second operating pressure by the atomic layer deposition process.
